(19) United States
(12) Patent Application Publication
(10) Pub. No.: US 2025/0079134 A1
(43) Pub. Date: Mar. 6, 2025

(54) MEMBER FOR SEMICONDUCTOR MANUFACTURING APPARATUS

(71) Applicant: NGK INSULATORS, LTD., Nagoya-City (JP)

(72) Inventors: Tatsuya KUNO, Nagoya-City (JP); Seiya INOUE, Handa-City (JP)

(73) Assignee: NGK INSULATORS, LTD., Nagoya-City (JP)

(21) Appl. No.: 18/588,280

(22) Filed: Feb. 27, 2024

Related U.S. Application Data
(63) Continuation of application No. PCT/JP2023/031085, filed on Aug. 29, 2023.

(51) Int. Cl. H01J 37/32; H01L 21/683

(52) U.S. Cl. CPC H01J 37/32642; H01L 21/6833; H01J 2237/3323; H01J 2237/3343

(57) ABSTRACT

A member for semiconductor manufacturing apparatus includes a central ceramic member having a wafer placement surface on an upper surface; an annular outer circumferential ceramic member having a focus ring placement surface on an upper surface; and a conductive base member having a central support joined to the central ceramic member, and an outer circumferential support joined to the outer circumferential ceramic member, wherein an outer circumferential surface of the central ceramic member and an inner circumferential surface of the outer circumferential ceramic member each change in diameter in an up-down direction, and a maximum diameter of the outer circumferential surface of the central ceramic member is smaller than a maximum diameter of the inner circumferential surface of the outer circumferential ceramic member, and larger than a minimum diameter of the inner circumferential surface of the outer circumferential ceramic member, and the central ceramic member is insulating ceramics.

### BACKGROUND OF THE INVENTION

### 1. Field of the Invention

The present invention relates to a member for semiconductor manufacturing apparatus.

### 2. Description of the Related Art

Conventionally, members for semiconductor manufacturing apparatus have been known which are used to perform CVD and etching on a wafer by utilizing plasma. In the members for semiconductor manufacturing apparatus like this, a focus ring may be used on the outer circumference of the wafer to obtain uniformity of plasma in the outer circumferential portion of the wafer. For example, the holding device in PTL 1 includes a central electrostatic chuck portion that mainly holds the wafer, and an outer circumferential electrostatic chuck portion that mainly holds the focus ring. The central electrostatic chuck portion includes, on the upper surface, a central ceramic member by which a wafer is attracted, and a metallic central base member joined to the lower surface of the central ceramic member by a resin central joint. The outer circumferential electrostatic chuck portion includes, on the upper surface, an outer circumferential ceramic member by which a focus ring is attracted, and a metallic central base member joined to the lower surface of the outer circumferential ceramic member by a resin outer circumferential joint. The outer circumferential electrostatic chuck portion is a substantially circular ring-shaped member that surrounds the central electrostatic chuck portion in a plan view. The outer circumferential electrostatic chuck portion is separated from the central electrostatic chuck portion, and a gap is provided between the outer circumferential electrostatic chuck portion and the central electrostatic chuck portion.

### CITATION LIST

### Patent Literature

PTL 1: JP 7152926 B

### SUMMARY OF THE INVENTION

Meanwhile, like the holding device in PTL 1, in a member for semiconductor manufacturing apparatus with a gap present between the central electrostatic chuck portion and the outer circumferential electrostatic chuck portion, a metallic base member or a resin joint which is exposed to the gap may corrode, and the apparatus life may be reduced. According to the knowledge of the inventors, such reduction in the life occurs due to the following reason: ions, such as argon, which are used in plasma processing are accelerated toward the member for semiconductor manufacturing apparatus and enter the gap, then collide with other atoms and molecules in the gap to generate plasma and radicals, which corrode the metal and resin in the periphery.

The present invention has been devised to solve such a problem, and it is a main object to inhibit reduction in the apparatus life.

[1] A member for semiconductor manufacturing apparatus of the present invention includes: a central ceramic member having a wafer placement surface on an upper surface; an annular outer circumferential ceramic member disposed on an outer circumferential side of the central ceramic member, the annular outer circumferential ceramic member having a focus ring placement surface on an upper surface; and a conductive base member having a central support joined to a lower surface of the central ceramic member to support the central ceramic member, and an outer circumferential support joined to a lower surface of the outer circumferential ceramic member to support the outer circumferential ceramic member, the central support and the outer circumferential support being configured to be separated or integrated. An outer circumferential surface of the central ceramic member and an inner circumferential surface of the outer circumferential ceramic member each change in diameter in an up-down direction, and a maximum diameter of the outer circumferential surface of the central ceramic member is smaller than a maximum diameter of the inner circumferential surface of the outer circumferential ceramic member, and larger than a minimum diameter of the inner circumferential surface of the outer circumferential ceramic member.

In the member for semiconductor manufacturing apparatus, the outer circumferential surface of the central ceramic member and the inner circumferential surface of the outer circumferential ceramic member each change in diameter in the up-down direction. The maximum diameter of the outer circumferential surface of the central ceramic member is smaller than the maximum diameter of the inner circumferential surface of the outer circumferential ceramic member, and larger than the minimum diameter of the inner circumferential surface of the outer circumferential ceramic member. Thus, when the member for semiconductor manufacturing apparatus is seen in a plan view, the outer circumferential portion of the central ceramic member overlaps with the inner circumferential portion of the outer circumferential ceramic member. In the member for semiconductor manufacturing apparatus like this, at the time of plasma processing, the ions accelerated toward the member for semiconductor manufacturing apparatus collide with the ceramic member before reaching the base member or the joint, and do not proceed any further. Thus, plasma and radicals are inhibited from being generated in the periphery of the base member and the joint, and as a result, reduction in the apparatus life can be inhibited.

Note that in the present specification, the present invention is described using the upper and lower, the right and left, the front and back, however, the upper and lower, the right and left, the front and back indicate only a relative positional relationship. Thus, when the orientation of the member for semiconductor manufacturing apparatus is changed, the upper and lower may become the right and left, or the right and left may become the upper and lower, and such a case is also included in the technical scope of the present invention.

[2] In the member for semiconductor manufacturing apparatus (the member for semiconductor manufacturing apparatus according to [1]) of the present invention, a minimum diameter of the outer circumferential surface of the central ceramic member may be smaller than a minimum diameter of the inner circumferential surface of the outer circumferential ceramic member. The central ceramic member and the outer circumferential ceramic member like this can be produced, for example, by hollowing out a piece of ceramic plate.

[3] In the member for semiconductor manufacturing apparatus (the member for semiconductor manufacturing apparatus according to [1] or [2]) of the present invention, in a cross section obtained by cutting the member for semiconductor manufacturing apparatus in a direction perpendicular to the wafer placement surface, the outer circumferential surface of the central ceramic member and the inner circumferential surface of the outer circumferential ceramic member each may appear as a diagonal line. The central ceramic member and the outer circumferential ceramic member like this can be produced, for example, by hollowing out a piece of ceramic plate into a circular truncated cone shape or an inverted circular truncated cone shape.

[4] In the member for semiconductor manufacturing apparatus (the member for semiconductor manufacturing apparatus according to any one of [1] to [3]) of the present invention, the outer circumferential surface of the central ceramic member may be a tapered surface which has a larger diameter at an upper position.

[5] In the member for semiconductor manufacturing apparatus (the member for semiconductor manufacturing apparatus according to any one of [1] to [3]) of the present invention, the outer circumferential surface of the central ceramic member may be a tapered surface which has a smaller diameter at an upper position.

[6] In the member for semiconductor manufacturing apparatus (the member for semiconductor manufacturing apparatus according to any one of [1] to [5]) of the present invention, the outer circumferential support may be an annular part disposed on an outer circumference of the central support with a gap from the central support. With this setting, the temperature of the outer circumferential support and the temperature of the central support are easily controlled independently, and eventually, the temperature of the wafer placement surface and the temperature of the focus ring placement surface are easily controlled independently.

[7] In the member for semiconductor manufacturing apparatus (the member for semiconductor manufacturing apparatus according to [6]) of the present invention, the central ceramic member and the central support may be joined by a metallic central joint, an outer circumferential surface of the central joint along with an outer circumferential surface of the central support may be covered by a central insulating film, the outer circumferential ceramic member and the outer circumferential support may be joined by a metallic outer circumferential joint, and an inner circumferential surface of the outer circumferential joint along with an inner circumferential surface of the outer circumferential support may be covered by an outer circumferential insulating film. With this setting, the joint and the base member are covered by an insulating film, thus corrosion of the joint and the base member is further inhibited. Since the joint is not made of resin but is made of metal, even when an insulating film is formed by thermal spraying, the joint is unlikely to metamorphose.

[8] In the member for semiconductor manufacturing apparatus (the member for semiconductor manufacturing apparatus according to any one of [1] to [6]) of the present invention, the central ceramic member and the central support may be joined by a resin central joint, and the outer circumferential ceramic member and the outer circumferential support may be joined by a resin outer circumferential joint. A resin adhesive layer is likely to corrode, thus application of the present invention has high significance.

[9] Alternatively, a member for semiconductor manufacturing apparatus of the present invention may be a member for placing a focus ring, the member for semiconductor manufacturing apparatus including: an annular outer circumferential ceramic member having a focus ring placement surface on an upper surface and being configured to be disposed on an outer circumferential side of a central ceramic member having a wafer placement surface; and a conductive base member having an outer circumferential support that supports the outer circumferential ceramic member, the conductive base member being joined to a lower surface of the outer circumferential ceramic member. An inner circumferential surface of the outer circumferential ceramic member changes in diameter in an up-down direction, the inner circumferential surface of the outer circumferential ceramic member being a tapered surface which has a larger diameter at an upper position or a smaller diameter at an upper position.

### BRIEF DESCRIPTION OF THE DRAWINGS

FIG. 1 is a vertical cross-sectional view of a member 10 for semiconductor manufacturing apparatus.

FIG. 2 is a plan view of the member 10 for semiconductor manufacturing apparatus.

FIG. 3 is a partial enlarged view of FIG. 1.

FIGS. 4A to 4C are manufacturing process diagrams for a central ceramic member 22 and an outer circumferential ceramic member 32.

FIG. 5 is a vertical cross-sectional view of a member 10B for semiconductor manufacturing apparatus as another example.

FIG. 6 is a plan view of the member 10B for semiconductor manufacturing apparatus as another example.

FIG. 7 is a partial enlarged view of FIG. 5.

FIG. 8 is a vertical cross-sectional view of a member 10C for semiconductor manufacturing apparatus as another example.

FIG. 9 is a vertical cross-sectional view of a member 10D for semiconductor manufacturing apparatus as another example.

FIGS. 10A and 10B are partial enlarged views of a member 110 for semiconductor manufacturing apparatus as a comparative example.

### DETAILED DESCRIPTION OF THE INVENTION

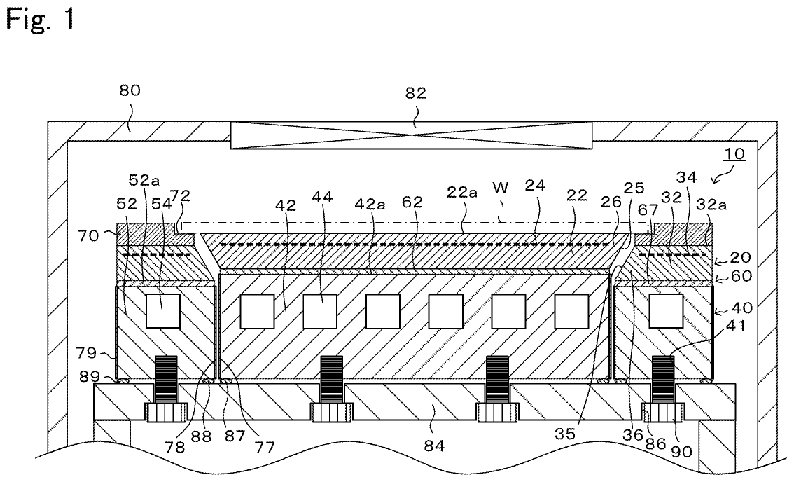

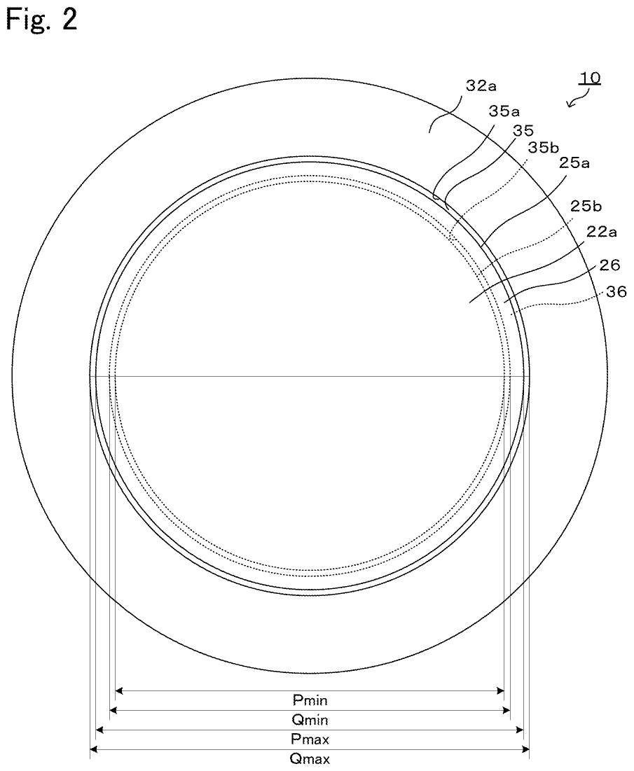

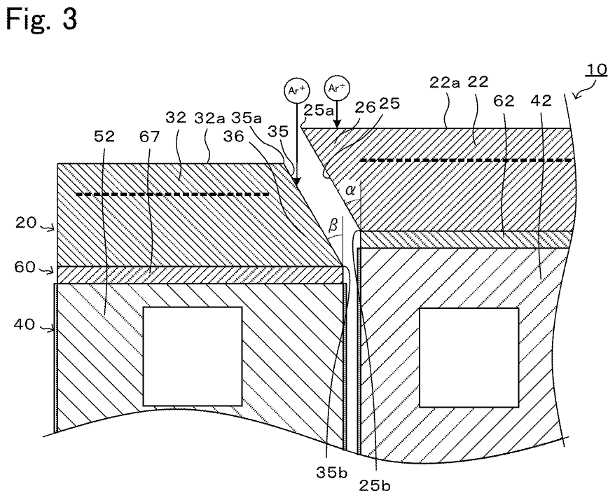

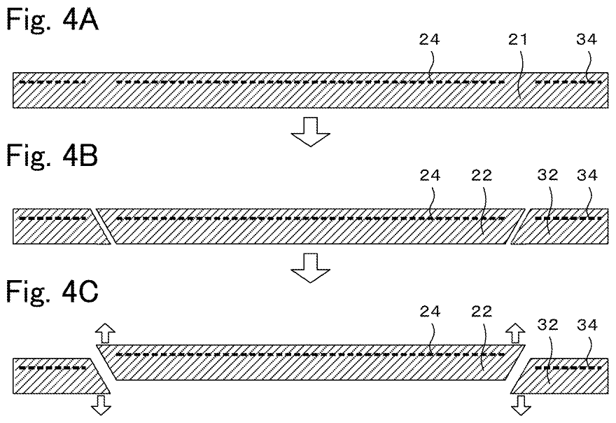

A preferred embodiment of the present invention will be described below with reference to the drawings. FIG. 1 is a vertical cross-sectional view (cross-sectional view when a member 10 for semiconductor manufacturing apparatus is cut along a plane including the central axis thereof) of a member 10 for semiconductor manufacturing apparatus. FIG. 2 is a plan view of the member 10 for semiconductor manufacturing apparatus. FIG. 3 is a partial enlarged view of FIG. 1. FIGS. 4A to 4C are manufacturing process diagrams for a central ceramic member 22 and an outer circumferential ceramic member 32.

The member 10 for semiconductor manufacturing apparatus is to be used for performing CVD and etching on a wafer W by utilizing plasma, and is fixed to an installation plate 84 provided inside a chamber 80 for semiconductor process. The member 10 for semiconductor manufacturing apparatus includes a central ceramic member 22, an outer circumferential ceramic member 32, and a base member 40. In the present embodiment, the base member 40 includes a central base member 42 as a center support, and an outer circumferential base member 52 as an outer circumferential support. The central ceramic member 22 and the central base member 42 are joined by a central joint 62. The outer circumferential ceramic member 32 and the outer circumferential base member 52 are joined by an outer circumferential joint 67. The central ceramic member 22 and the outer circumferential ceramic member 32 are also collectively referred to as a ceramic member 20. The central joint 62 and the outer circumferential joint 67 are also collectively referred to as a joint 60. The member 10 for semiconductor manufacturing apparatus may include a focus ring 70. Hereinafter, the “focus ring” is abbreviated as “FR”.

The central ceramic member 22 is a ceramic disk member, and has a circular wafer placement surface 22a on the upper surface. A wafer W is placed on the wafer placement surface 22a. The diameter of the wafer placement surface 22a is smaller than the diameter (e.g., 300 mm) of the wafer W. The central ceramic member 22 is made of a ceramic material represented by alumina, aluminum nitride. The central ceramic member 22 has a built-in wafer attraction electrode 24. The wafer attraction electrode 24 is made of a material containing e.g., W, Mo, WC, MOC. The wafer attraction electrode 24 is a plate-shaped or mesh-shaped monopolar electrostatic electrode. The layer of the central ceramic member 22, above the wafer attraction electrode 24 functions as a dielectric layer. The wafer attraction electrode 24 is connected to a wafer attraction DC power supply which is not illustrated.

The outer circumferential ceramic member 32 is an annular member, and has an annular FR placement surface 32a on the upper surface. The outer circumferential ceramic member 32 is separated from the central ceramic member 22, and disposed on the outer circumferential side of the central ceramic member 22 with a gap from the central ceramic member 22. The FR placement surface 32a is provided at a position lower than the wafer placement surface 22a by one step. An FR 70 is placed on the FR placement surface 32a. The inner diameter of the FR placement surface 32a is substantially the same as the inner diameter of the FR 70. The outer circumferential ceramic member 32 is made of a ceramic material represented by alumina, aluminum nitride. The outer circumferential ceramic member 32 has a built-in FR attraction electrode 34. The FR attraction electrode 34 is made of a material containing e.g., W, Mo, WC, MOC. The FR attraction electrode 34 is a plate-shaped or mesh-shaped monopolar electrostatic electrode. The layer of the outer circumferential ceramic member 32, above the FR attraction electrode 34 functions as a dielectric layer. The FR attraction electrode 34 is connected to an FR attraction DC power supply which is not illustrated. The outer circumferential ceramic member 32 may have the same thickness as that of the central ceramic member 22.

An outer circumferential surface 25 of the central ceramic member 22 has a tapered surface (the outer lateral surface of an inverted circular truncated cone) which has a larger diameter at an upper position. As illustrated in FIG. 3, the outer circumferential surface 25 of the central ceramic member 22 is inclined from a lower end 25b as a start point by an angle α toward the outer circumferential side with respect to the up-down direction. The angle α is e.g., 10° or greater and 80° or less. An inner circumferential surface 35 of the outer circumferential ceramic member 32 is a tapered surface (the inner surface obtained by hollowing out an inverted circular truncated cone from a disk) which has a larger diameter at an upper position. As illustrated in FIG. 3, the inner circumferential surface 35 of the outer circumferential ceramic member 32 is inclined from a lower end 35b as a start point by an angle β toward the outer circumferential side with respect to the up-down direction. The angle β is e.g., 10° or greater and 80° or less. The angle β may be the same as or different from the angle α. As illustrated in FIG. 2, maximum diameter Pmax (the diameter at an upper end 25a of the outer circumferential surface 25 in the present embodiment) of the outer circumferential surface 25 of the central ceramic member 22 is smaller than maximum diameter Qmax (the diameter at an upper end 35a of the inner circumferential surface 35 in the present embodiment) of the inner circumferential surface 35 of the outer circumferential ceramic member 32, and is greater than minimum diameter Qmin (the diameter at a lower end 35b of the inner circumferential surface 35 in the present embodiment) of the inner circumferential surface 35 of the outer circumferential ceramic member 32. Thus, when the member 10 for semiconductor manufacturing apparatus is seen in a plan view, an outer circumferential portion 26 of the central ceramic member 22 overlaps with an inner circumferential portion 36 of the outer circumferential ceramic member 32. Note that when the member 10 for semiconductor manufacturing apparatus is seen in a plan view, the inner circumferential surface 35 of the outer circumferential ceramic member 32 is between the wafer placement surface 22a and the FR placement surface 32a, and it is not possible to see beyond the inner circumferential surface 35

The central ceramic member 22 and the outer circumferential ceramic member 32 may be manufactured, for example, as follows. FIGS. 4A to 4C are manufacturing process diagrams for the central ceramic member 22 and the outer circumferential ceramic member 32. First, as illustrated in FIG. 4A, a piece of ceramic plate 21 with the wafer attraction electrode 24 and the FR attraction electrode 34 embedded is prepared. The ceramic plate 21 is produced, for example, as follows. First, two pieces of a disk molded body made of ceramic powder are produced. Subsequently, a central print electrode having the same shape as the wafer attraction electrode 24, and an outer circumferential print electrode having the same shape as the FR attraction electrode 34 are printed on the upper surface of the first disk molded body so as to be concentric with the disk molded body. Then the second disk molded body is layered on the print electrode surface of the first disk molded body to produce a layered body. Hot-press firing is performed on the layered body to obtain the ceramic plate 21. Next, as illustrated in FIG. 4B, a disk-shaped central portion is hollowed out from the ceramic plate 21 by machining to have a separated circular ring-shaped outer circumferential portion, and the central ceramic member 22 and the outer circumferential ceramic member 32 are obtained. When a disk-shaped central portion is hollowed out, machining is performed so that the disk-shaped central portion has an inverted circular truncated cone shape. When the central ceramic member 22 and the outer circumferential ceramic member 32 are produced from a piece of ceramic plate in this manner, the manufacturing cost is likely to reduce as compared to when a ceramic plate for the central ceramic member 22 and a ceramic plate for the outer circumferential ceramic member 32 are individually prepared. As illustrated in FIG. 4C, the size of the gap between the central ceramic member 22 and the outer circumferential ceramic member 32 produced in this manner can be adjusted by displacing the relative position between both members in an up-down direction. Note that the outer circumferential surface 25 of the obtained central ceramic member 22 and the inner circumferential surface 35 of the obtained outer circumferential ceramic member 32 may be provided with concavities and convexities by further performing machining on the surfaces.

The central base member 42 is a conductive disk member, and has a circular center support surface 42a on the upper surface. The central ceramic member 22 is joined to the center support surface 42a. The diameter of the central support surface 42a is the same as the diameter of the lower surface of the central ceramic member 22. The central base member 42 internally has a central refrigerant flow path 44 through which a refrigerant can be circulated. The central refrigerant flow path 44 is provided over the entirety of the central base member 42 in a one-stroke pattern in a plan view. The refrigerant which flows through the central refrigerant flow path 44 is preferably liquid, and preferably has electrical insulating properties. As liquid having electrical insulating properties, e.g., fluorine-based inert liquid may be mentioned. The central base member 42 is made of e.g., a conductive material containing metal. As the conductive material, e.g., metal and a composite material may be mentioned. As the metal, Al, Ti, Mo or an alloy thereof may be mentioned. As the composite material, metal matrix composite material (MMC) and a ceramic matrix composite material (CMC) may be mentioned. As a specific example of such a composite material, a material containing Si, SiC and Ti, and a material obtained by impregnating a SiC porous body with Al and/or Si may be mentioned. The material containing Si, SiC and Ti is referred to as SisiCTi, the material obtained by impregnating a SiC porous body with Al is referred to as AlsiC, and the material obtained by impregnating a sic porous body with Si is referred to as SisiC. From the viewpoint of increasing the cooling efficiency, as the material for the central base member 42, a material having a high thermal conductivity is preferably selected, and e.g., Al and Al alloy are preferable. From the viewpoint of inhibiting damage due to thermal stress, as the material for the central base member 42, a material having a coefficient of thermal expansion closer to that of the material for the central ceramic member 22 is preferably selected, and a composite material of e.g., metal and ceramic is preferable. The central base member 42 is also used as an RF electrode. A central insulating film 77 made of an insulating material (e.g., alumina or yttria) is formed on the outer circumferential surface of the central base member 42. The central insulating film 77 may be a thermally sprayed film.

The outer circumferential base member 52 is a conductive annular member, and has an annular outer circumferential support surface 52a on the upper surface. The outer circumferential base member 52 is separated from the central base member 42, and disposed on the outer circumferential side of the central base member 42 with a gap from the central base member 42. The outer circumferential support surface 52a is provided at a position lower than the central support surface 42a by one step. The outer circumferential ceramic member 32 is joined to the outer circumferential support surface 52a. The inner diameter and the outer diameter of the outer circumferential support surface 52a are the same as the inner diameter and the outer diameter, respectively, of the lower surface of the outer circumferential ceramic member 32. The outer circumferential base member 52 internally has an outer circumferential refrigerant flow path 54 through which a refrigerant can be circulated. The outer circumferential refrigerant flow path 54 is provided over the entirety of the outer circumferential base member 52 in a one-stroke pattern in a plan view. The refrigerant which flows through the outer circumferential refrigerant flow path 54 is preferably liquid, and preferably has electrical insulating properties. As liquid having electrical insulating properties, e.g., fluorine-based inert liquid may be mentioned. The outer circumferential base member 52 is made of e.g., a conductive material containing metal. As the conductive material, the material illustrated for the central base member 42 may be mentioned. From the viewpoint of increasing the cooling efficiency, as the material for the outer circumferential base member 52, a material having a high thermal conductivity is preferably selected, and e.g., Al and Al alloy are preferable. From the viewpoint of inhibiting damage due to thermal stress, as the material for the outer circumferential base member 52, a material having a coefficient of thermal expansion closer to that of the material for the outer circumferential ceramic member 32 is preferably selected, and a composite material of e.g., metal and ceramic is preferable. The outer circumferential base member 52 is also used as an RF electrode. An outer circumferential insulating film 78 made of an insulating material (e.g., alumina or yttria) is formed on the inner circumferential surface of the outer circumferential base member 52. In addition, an outermost circumferential insulating film 79 made of an insulating material (e.g., alumina or yttria) is formed on the outer circumferential surface of the outer circumferential base member 52. The outer circumferential insulating film 78 and the outermost circumferential insulating film 79 may be a thermally sprayed film.

The central joint 62 joins the lower surface of the central ceramic member 22 and the upper surface of the central base member 42. In the present embodiment, the central joint 62 is a resin adhesive layer. As the resin, resin such as, acrylic resin, silicone resin, and epoxy resin, may be used. A filler may be further contained in the adhesive layer.

The outer circumferential joint 67 joins the lower surface of the outer circumferential ceramic member 32 and the upper surface of the outer circumferential base member 52. In the present embodiment, the outer circumferential joint 67 is a resin adhesive layer. As the resin, resin such as, acrylic resin, silicone resin, and epoxy resin, may be used. A filler may be further contained in the adhesive layer.

The FR 70 is an annular member placed on the FR placement surface 32a, and made of e.g., silicon. An upper portion of the inner circumferential surface of the FR 70 is provided with a step 72 in a circumferential direction. The step 72 is provided to prevent the wafer W from interfering with the FR 70. The inner diameter of the FR 70 is substantially the same as the inner diameter of the FR placement surface 32a.

Next, an example of use of the member 10 for semiconductor manufacturing apparatus will be described with reference to FIG. 1. The chamber 80 has a shower head 82 in a ceiling surface. The member 10 for semiconductor manufacturing apparatus is fixed to the installation plate 84 disposed inside the chamber 80. Specifically, O-rings 87, 88, 89 are disposed concentrically between the lower surface of the base member 40 and the upper surface of the installation plate 84, and in this state, the member 10 for semiconductor manufacturing apparatus is fixed to the installation plate 84 by securing the installation plate 84 and the base member 40 by a plurality of bolts 90. The O-ring 87 has substantially the same diameter as the diameter of the central base member 42, the O-ring 88 has substantially the same diameter as the inner diameter of the outer circumferential base member 52, and the O-ring 89 has substantially the same diameter as the outer diameter of the outer circumferential base member 52. Each bolt 90 has a head and a foot. The bolt 90 is inserted from below into a bolt insertion hole 86 with a step, the bolt insertion hole 86 penetrating in an up-down direction the installation plate 84, and the foot is screwed into a threaded hole 41 provided in the lower surface of the base member 40. At this point, the head of the bolt 90 is engaged with the step of the bolt insertion hole 86. The O-rings 87, 88, 89 are crushed in an up-down direction to exhibit a sealing property. When there is a point where the sealing property is necessary additionally, an O-ring is separately disposed at the point.

When the wafer W is processed using the member 10 for semiconductor manufacturing apparatus, the processing is performed with the FR 70 placed on the FR placement surface 32a of the member 10 for semiconductor manufacturing apparatus, and the disk-shaped wafer W placed on the wafer placement surface 22a. In this state, a DC voltage is applied to the wafer attraction electrode 24 to cause the wafer W to be attracted to the wafer placement surface 22a, and a DC voltage is applied to the FR attraction electrode 34 to cause the FR 70 to be attracted to the FR placement surface 32a. Setting is made so that a predetermined vacuum atmosphere (or a reduced pressure atmosphere) is created inside the chamber 80, and a high frequency voltage is applied across the shower head 82 and the base member 40 while supplying a process gas from the shower head 82. Then, plasma is generated between the base member 40 and the shower head 82. The wafer W is then processed using the plasma.

Note that as the wafer W is plasma-processed, the FR 70 is also worn out, but since the FR 70 is thicker than the wafer W, the FR 70 is replaced after several wafers W are processed.

When the member 10 for semiconductor manufacturing apparatus itself is dry cleaned, the dry cleaning may be performed with the wafer W not placed on the wafer placement surface 22a of the member 10 for semiconductor manufacturing apparatus (waferless dry cleaning). The waferless dry cleaning may be performed with the FR 70 placed on the FR ring placement surface 32a or performed with the FR 70 not placed on the FR ring placement surface 32a. When the waferless dry cleaning is performed with the FR placed, a DC voltage is applied to the FR attraction electrode 34 to cause the FR 70 to be attracted to the FR placement surface 32a. Setting is made so that a predetermined vacuum atmosphere (or a reduced pressure atmosphere) is created inside the chamber 80, and a high frequency voltage is applied across the shower head 82 and the base member 40 while supplying a cleaning gas from the shower head 82. Then, plasma is generated between the base member 40 and the shower head 82. The member 10 for semiconductor manufacturing apparatus is cleaned utilizing the plasma.

When the member 10 for semiconductor manufacturing apparatus is used, the ions (e.g., argon ions) in the plasma generated between the base member 40 and the shower head 82 are accelerated toward the member 10 for semiconductor manufacturing apparatus in a direction substantially perpendicular to the wafer placement surface 22a and the FR placement surface 32a. The accelerated ions collide with other molecules and atoms (e.g., the atoms and molecules in a corrosive gas) to generate plasma and radicals, which may corrode the metal and resin in the periphery. Particularly when the waferless dry cleaning is performed, the occurrence of such corrosion is of concern.

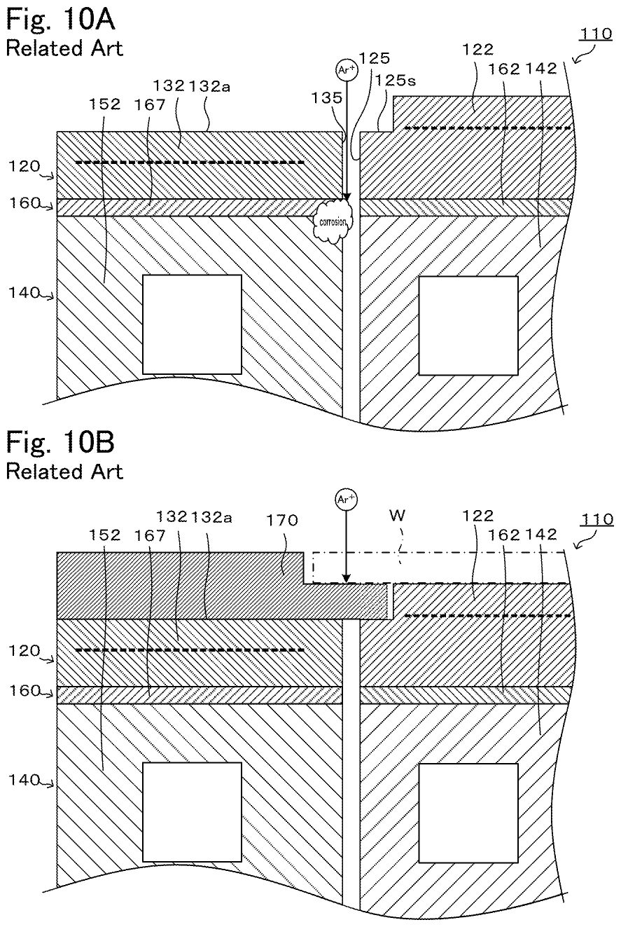

This point will be described in detail below. FIGS. 10A and 10B are partial enlarged views of a member 110 for semiconductor manufacturing apparatus in a comparative embodiment (an embodiment of a conventional technique disclosed in PTL 1). In the member 110 for semiconductor manufacturing apparatus, an outer circumferential surface 125 of a central ceramic member 122 and an inner circumferential surface 135 of an outer circumferential ceramic member 132 each have a constant diameter in the up-down direction, and when the member 110 for semiconductor manufacturing apparatus is seen in a plan view, the central ceramic member 122 does not overlap with the outer circumferential ceramic member 132, and it is possible to see the gap between the both to the furthest depth. In the member 110 for semiconductor manufacturing apparatus like this, as illustrated in FIG. 10A, the accelerated ions enter the gap between a central base member 142 and an outer circumferential base member 152 as well as the gap between a central joint 162 and an outer circumferential joint 167. Then the accelerated ions collide with other atoms and molecules in the gap to generate plasma and radicals, which corrode a base member 140 and a joint 160 in the periphery, and reduces the life of the member 110 for semiconductor manufacturing apparatus. Note that in the member 110 for semiconductor manufacturing apparatus, the outer circumferential surface 125 of the central ceramic member 122 has a step 125s in a circumferential direction, which has a smaller diameter above, and the inner circumferential portion of an FR 170 is disposed in the step 125s as illustrated in FIG. 10B. Consequently, when waferless dry cleaning is performed with the FR 170 placed on an FR placement surface 132a, the accelerated ions collide with the FR 170 and do not proceed any further, thus corrosion of the base member 140 and the joint 160 is inhibited. However, since waferless dry cleaning is performed with the FR 170 placed on an FR placement surface 132a, the FR 170 is corroded by the accelerated ions to reduce the life of the FR 170. Therefore, when the member 110 for semiconductor manufacturing apparatus is used, the running cost of the entire semiconductor manufacturing apparatus increases to reduce the apparatus life.

In contrast, in the present embodiment, the outer circumferential surface 25 of the central ceramic member 22 and the inner circumferential surface 35 of the outer circumferential ceramic member 32 each change in diameter in the up-down direction, and when the member 10 for semiconductor manufacturing apparatus is seen in a plan view, the outer circumferential portion 26 of the central ceramic member 22 overlaps with the inner circumferential portion 36 of the outer circumferential ceramic member 32. In the member 10 for semiconductor manufacturing apparatus like this, as illustrated in FIG. 3, the accelerated ions collide with the ceramic member 20 before reaching the base member 40 or the joint 60, and do not proceed any further. Thus, plasma and radicals are inhibited from being generated in the periphery of the base member 40 and the joint 60, corrosion of the base member 40 and the joint 60 is inhibited, and as a result, reduction in the apparatus life is inhibited. In a plan view of the member 10 for semiconductor manufacturing apparatus, the outer circumferential portion 26 of the central ceramic member 22 overlaps with the inner circumferential portion 36 of the outer circumferential ceramic member 32, thus even when waferless dry cleaning is performed with the FR 70 not placed on the FR placement surface 32a, corrosion of the base member 40 and the joint 60 can be inhibited. Therefore, the life of the FR 70 can be improved, and the apparatus life of the entire semiconductor manufacturing apparatus can be inhibited from being reduced.

In the member 10 for semiconductor manufacturing apparatus described above, the outer circumferential surface 25 of the central ceramic member 22 and the inner circumferential surface 35 of the outer circumferential ceramic member 32 each change in diameter in the up-down direction. The maximum diameter Pmax of the outer circumferential surface 25 of the central ceramic member 22 is smaller than the maximum diameter Qmax of the inner circumferential surface 35 of the outer circumferential ceramic member 32, and larger than the minimum diameter Qmin of the inner circumferential surface 35 of the outer circumferential ceramic member 32. Thus, when the member 10 for semiconductor manufacturing apparatus is seen in a plan view, the outer circumferential portion 26 of the central ceramic member 22 overlaps with the inner circumferential portion 36 of the outer circumferential ceramic member 32. Therefore, as described above, reduction in the apparatus life is inhibited.

The minimum diameter Pmin (the diameter at the lower end 25b of the outer circumferential surface 25 in the present embodiment) of the outer circumferential surface 25 of the central ceramic member 22 is smaller than the minimum diameter Qmin of the inner circumferential surface 35 of the outer circumferential ceramic member 32. The central ceramic member 22 and the outer circumferential ceramic member 32 like this can be produced, for example, by hollowing out a piece of ceramic plate. In this case, the manufacturing cost is likely to reduce as compared to when a ceramic plate for the central ceramic member 22 and a ceramic plate for the outer circumferential ceramic member 32 are individually prepared.

Furthermore, in the cross-section of the member 10 for semiconductor manufacturing apparatus when cut in the direction perpendicular to the wafer placement surface 22a, the outer circumferential surface 25 of the central ceramic member 22 and the inner circumferential surface 35 of the outer circumferential ceramic member 32 each appear as a diagonal line. The central ceramic member 22 and the outer circumferential ceramic member 32 like this can be produced, for example, by hollowing out a piece of ceramic plate into a circular truncated cone shape or an inverted circular truncated cone shape. Hollowing out such as a shape is relatively easy, and the manufacturing cost is likely to reduce.

Furthermore, the outer circumferential base member 52 as the outer circumferential support is an annular member that is disposed with a gap from the central base member 42 as the central support. Therefore, the temperature of the outer circumferential base member 52 and the temperature of the central base member 42 are easily controlled independently, and eventually, the temperature of the wafer placement surface 22a and the temperature of the FR placement surface 32a are easily controlled independently.

Then the central ceramic member 22, and the central base member 42 as the central support are joined by the resin central joint 62, and the outer circumferential ceramic member 32, and the outer circumferential base member 52 as the outer circumferential support are joined by the resin outer circumferential joint 67. A resin adhesive layer is likely to corrode, thus application of the present invention has high significance.

Note that the present invention is not limited to the above-described embodiment at all, and it is needless to say that the present invention can be carried out in various forms as long as the forms belong to the technical scope of the present invention.

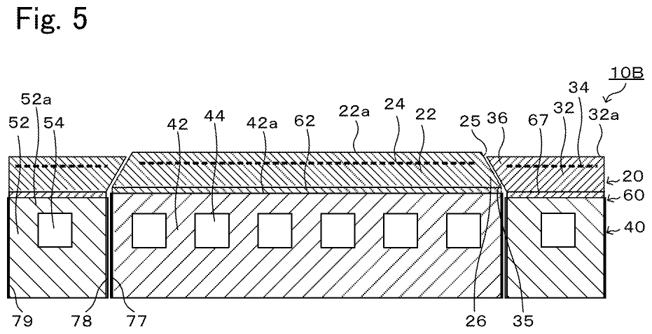

In the above-described embodiment, the outer circumferential surface 25 of the central ceramic member 22 is a tapered surface which has a larger diameter at an upper position, but is not limited thereto as long as the outer circumferential surface 25 changes in diameter in the up-down direction. The outer circumferential surface 25 of the central ceramic member 22 may be e.g., a tapered surface (the outer lateral surface of a circular truncated cone) which has a smaller diameter at an upper position as in a member 10B for semiconductor manufacturing apparatus as another example illustrated in FIG. 5 to FIG. 7. In the above-described embodiment, the inner circumferential surface 35 of the outer circumferential ceramic member 32 is a tapered surface which has a larger diameter at an upper position, but is not limited thereto as long as the inner circumferential surface 35 changes in diameter in the up-down direction. The inner circumferential surface 35 of the outer circumferential ceramic member 32 may be e.g., a tapered surface (the inner lateral surface of a disk when a circular truncated cone hollowed out from the disk) which has a smaller diameter at an upper position as in the member 10B for semiconductor manufacturing apparatus. Note that in FIGS. 5 to 7, the same components as in the above-described embodiment are labeled with the same symbol.

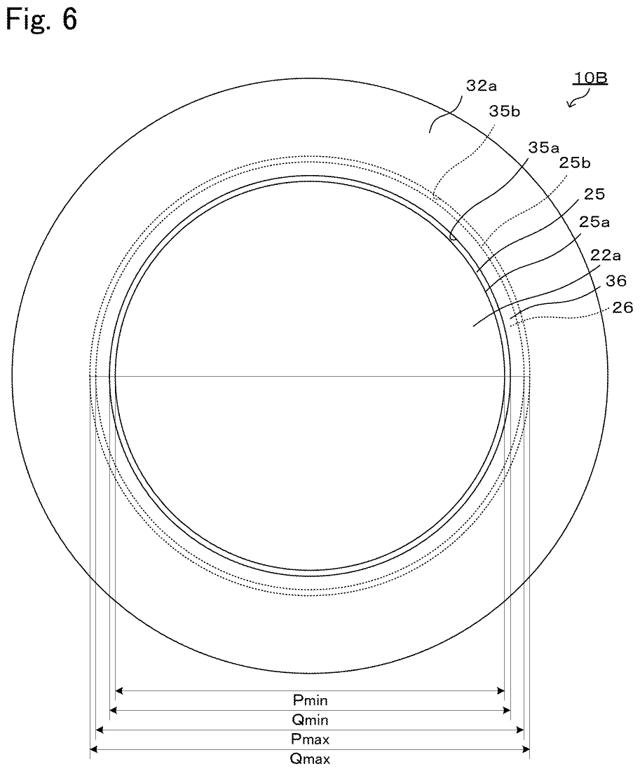

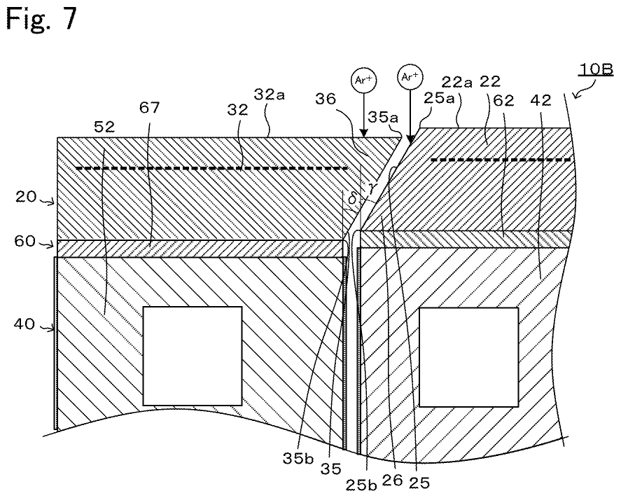

In the member 10B for semiconductor manufacturing apparatus, as illustrated in FIG. 7, the outer circumferential surface 25 of the central ceramic member 22 is inclined from the lower end 25b as a start point by an angle γ toward the inner circumferential side with respect to the up-down direction. The angle γ is e.g., 10° or greater and 80° or less. As illustrated in FIG. 7, the inner circumferential surface 35 of the outer circumferential ceramic member 32 is inclined from the lower end 35b as a start point by an angle δ toward the inner circumferential side with respect to the up-down direction. The angle δ is e.g., 10° or greater and 80° or less. The angle δ may be the same as or different from the angle γ. In the member 10B for semiconductor manufacturing apparatus, as illustrated in FIG. 6, the maximum diameter Pmax (the diameter at the lower end 25b of the outer circumferential surface 25 in another example) of the outer circumferential surface 25 of the central ceramic member 22 is smaller than the maximum diameter Qmax (the diameter at the lower end 35b of the inner circumferential surface 35 in another example) of the inner circumferential surface 35 of the outer circumferential ceramic member 32, and larger than the minimum diameter Qmin (the diameter at the upper end 35a of the inner circumferential surface 35 in another example) of the inner circumferential surface 35 of the outer circumferential ceramic member 32. Thus, when the member 10 for semiconductor manufacturing apparatus is seen in a plan view, the outer circumferential portion 26 of the central ceramic member 22 overlaps with the inner circumferential portion 36 of the outer circumferential ceramic member 32. Note that when the member 10B for semiconductor manufacturing apparatus is seen in a plan view, the outer circumferential surface 25 of the central ceramic member 22 is between the wafer placement surface 22a and the FR placement surface 32a, and it is not possible to see beyond the outer circumferential surface 25. In the member 10B for semiconductor manufacturing apparatus like this, as illustrated in FIG. 7, the accelerated ions collide with the ceramic member 20 before reaching the base member 40 or the joint 60, and do not proceed any further. Thus, plasma and radicals are inhibited from being generated in the periphery of the base member 40 and the joint 60, corrosion of the base member 40 and the joint 60 is inhibited, and as a result, reduction in the apparatus life is inhibited. Even when waferless dry cleaning is performed with the FR 70 not placed on the FR placement surface 32a, corrosion of the base member 40 and the joint 60 can be inhibited, thus the life of the FR 70 can be improved, and the apparatus life of the entire semiconductor manufacturing apparatus can be inhibited from being reduced.

In the member 10B for semiconductor manufacturing apparatus, the minimum diameter Pmin (the diameter at the lower end 25a of the outer circumferential surface 25 in the present embodiment) of the outer circumferential surface 25 of the central ceramic member 22 is smaller than the minimum diameter Qmin of the inner circumferential surface 35 of the outer circumferential ceramic member 32. The central ceramic member 22 and the outer circumferential ceramic member 32 like this can be produced, for example, by hollowing out a piece of ceramic plate.

The central ceramic member 22 and the outer circumferential ceramic member 32 of the member 10B for semiconductor manufacturing apparatus may be manufactured according to FIGS. 4A to 4C. In this case, when a disk-shaped central portion is hollowed out in FIG. 4B, processing should be performed so that the disk-shaped central portion has a circular truncated cone shape.

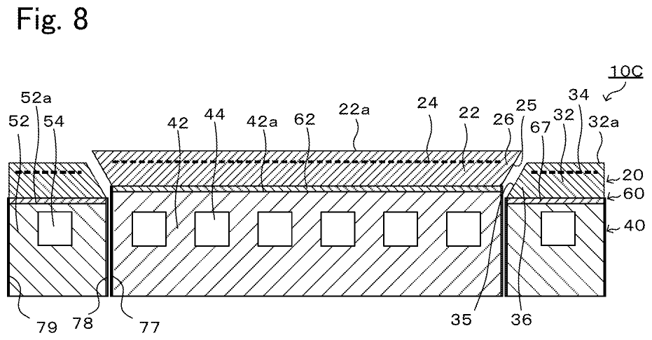

In the above-described embodiment and another example, the central joint 62 and the outer circumferential joint 67 are each a resin adhesive layer, but may be e.g., a metallic bonding layer made of solder or metal brazing material. The metallic bonding layer may be formed by e.g., TCB (Thermal compression bonding). The TCB is a publicly known method by which a metal bonding material is inserted between two members to be bonded, and the two members are pressurized and bonded with the two members heated at a temperature lower than or equal to the solidus temperature of the metal bonding material. When the central joint 62 and the outer circumferential joint 67 are metallic bonding layers, as in a member 10C for semiconductor manufacturing apparatus as another example illustrated in FIG. 8, the outer circumferential surface of the central joint 62 along with the outer circumferential surface of the central base member 42 as the central support may be covered by the central insulating film 77, and the outer circumferential surface of the outer circumferential joint 67 along with the inner circumferential surface of the outer circumferential base member 52 as the outer circumferential support may be covered by the outer circumferential insulating film 78. The outer circumferential surface of the outer circumferential joint 67 along with the outer circumferential surface of the outer circumferential base member 52 as the outer circumferential support may be covered by the outermost circumferential insulating film 79. With this setting, the joint 60 and the base member 40 are covered by an insulating film, thus corrosion of the joint 60 and the base member 40 is further inhibited. Since the joint 60 is not made of resin but is made of metal, even when an insulating film is formed by thermal spraying, the joint 60 is unlikely to metamorphose. In FIG. 8, the same components as in the above-described embodiment are labeled with the same symbol.

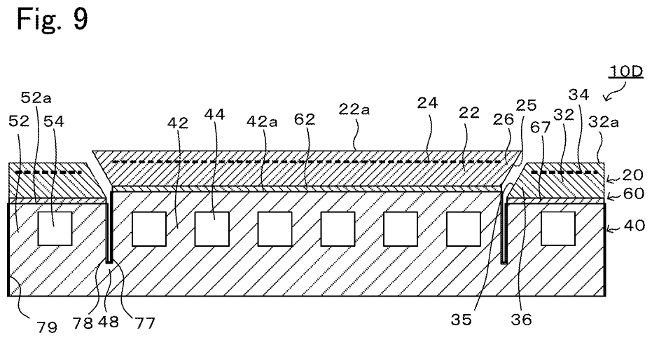

In the above-described embodiment and another example, in the base member 40, the central base member 42 as the central support, and the outer circumferential base member 52 as the outer circumferential support are separate members, but may be one-piece. In this case, as in a member 10D for semiconductor manufacturing apparatus as another example illustrated in FIG. 9, the base member 40 may be one-piece having a structure in which the central base member 42 and the outer circumferential base member 52 are connected by a connection part 48. In the member 10D for semiconductor manufacturing apparatus, the upper surface of the connection part 48 is also preferably provided with an insulating film similar to the central insulating film 77 or the outer circumferential insulating film 78. Note that in the base member 40, a gap may not be present between the central base member 42 and the outer circumferential base member 52, but providing a gap makes it easy to control the temperature of the outer circumferential base member 52 and the temperature of the central base member 42 independently, and eventually, makes it easy to control the temperature of the wafer placement surface 22a and the temperature of the FR placement surface 32a independently. In FIG. 9, the same components as in the above-described embodiment are labeled with the same symbol.

In the above-described embodiment and another example, the outer circumferential ceramic member 32 is disposed with a gap from the central ceramic member 22, but may be disposed without a gap (including the case where the joint 60 and the base member 40 are covered by a thermally sprayed film and no gap is created therebetween). Disposing those members without a gap makes it easy to control the temperature of the wafer placement surface 22a and the temperature of the focus ring placement surface 32a independently. In contrast, with those members disposed without a gap, when a high frequency voltage is applied across the shower head 82 and the base member 40, it is possible to inhibit abnormal discharge which may occur through a gap in the periphery of the base member 40.

In the above-described embodiment and another example, the members 10, 10B, 10C, 10D for semiconductor manufacturing apparatus are for placing the focus ring 70, the members 10, 10B, 10C, 10D including: an annular outer circumferential ceramic member 32 having the focus ring placement surface 32a on the upper surface and being configured to be disposed on the outer circumferential side of a central ceramic member having a wafer placement surface; and a conductive base member 40 that is joined to the lower surface of the outer circumferential ceramic member 32, and has an outer circumferential support member that supports the outer circumferential ceramic member 32. The inner circumferential surface 35 of the outer circumferential ceramic member 32 changes in diameter in the up-down direction, and is a tapered surface which has a larger diameter at an upper position or a smaller diameter at an upper position. In this case, the central ceramic member may be the same as or different from the above-described central ceramic member 22, or may be omitted. The base member 40 may be the same as the above-described base member 40, or may have a central support different from that of the above-described central base member 42, or may have no central support.

In the above-described embodiment and another example, a heater electrode for heating wafer may be embedded in the central ceramic member 22. With this setting, when the wafer W placed on the wafer placement surface 22a needs to be heated to a high temperature, the wafer W can be heated to a desired high temperature by turning on the heater electrode for heating wafer. In addition, a heater electrode for heating FR may be embedded in the outer circumferential ceramic member 32. With this setting, when the FR 70 placed on the FR placement surface 32a needs to be heated to a high temperature, the FR 70 can be heated to a desired high temperature by turning on the heater electrode for heating FR. When a heater electrode for heating wafer is embedded in the central ceramic member 22, and a heater electrode for heating FR is embedded in the outer circumferential ceramic member 32, it is preferable that the respective heater electrodes be individually temperature-adjustable.

International Application No. PCT/JP2023/031085, filed on Aug. 29, 2023, is incorporated herein by reference in its entirety.

What is claimed is:

1. A member for semiconductor manufacturing apparatus, comprising:
a central ceramic member having a wafer placement surface on an upper surface;
an annular outer circumferential ceramic member disposed on an outer circumferential side of the central ceramic member, the annular outer circumferential ceramic member having a focus ring placement surface on an upper surface; and
a conductive base member having a central support joined to a lower surface of the central ceramic member to support the central ceramic member, and an outer circumferential support joined to a lower surface of the outer circumferential ceramic member to support the outer circumferential ceramic member, the central support and the outer circumferential support being configured to be separated or integrated,
wherein an outer circumferential surface of the central ceramic member and an inner circumferential surface of the outer circumferential ceramic member each change in diameter in an up-down direction, and
a maximum diameter of the outer circumferential surface of the central ceramic member is smaller than a maximum diameter of the inner circumferential surface of the outer circumferential ceramic member, and larger than a minimum diameter of the inner circumferential surface of the outer circumferential ceramic member, and
the central ceramic member is insulating ceramics.

2. The member for semiconductor manufacturing apparatus according to claim 1,
wherein a minimum diameter of the outer circumferential surface of the central ceramic member is smaller than a minimum diameter of the inner circumferential surface of the outer circumferential ceramic member.

3. The member for semiconductor manufacturing apparatus according to claim 1,
wherein in a cross section obtained by cutting the member for semiconductor manufacturing apparatus in a direction perpendicular to the wafer placement surface, the outer circumferential surface of the central ceramic member and the inner circumferential surface of the outer circumferential ceramic member each appear as a diagonal line.

4. The member for semiconductor manufacturing apparatus according to claim 1,
wherein the outer circumferential surface of the central ceramic member is a tapered surface which has a larger diameter at an upper position.

5. The member for semiconductor manufacturing apparatus according to claim 1,
wherein the outer circumferential surface of the central ceramic member is a tapered surface which has a smaller diameter at an upper position.

6. The member for semiconductor manufacturing apparatus according to claim 1,
wherein the outer circumferential support is an annular part disposed on an outer circumference of the central support with a gap from the central support.

7. The member for semiconductor manufacturing apparatus according to claim 6,
wherein the central ceramic member and the central support are joined by a metallic central joint, an outer circumferential surface of the central joint along with an outer circumferential surface of the central support is covered by a central insulating film, the outer circumferential ceramic member and the outer circumferential support are joined by a metallic outer circumferential joint, and an inner circumferential surface of the outer circumferential joint along with an inner circumferential surface of the outer circumferential support is covered by an outer circumferential insulating film.

8. The member for semiconductor manufacturing apparatus according to claim 1,
wherein the central ceramic member and the central support are joined by a resin central joint, and the outer circumferential ceramic member and the outer circumferential support are joined by a resin outer circumferential joint.

9. The member for semiconductor manufacturing apparatus according to claim 1,
wherein the central ceramic member includes alumina or aluminum nitride.

10. A member for semiconductor manufacturing apparatus for placing a focus ring, the member for semiconductor manufacturing apparatus comprising:
an annular outer circumferential ceramic member having a focus ring placement surface on an upper surface and being configured to be disposed on an outer circumferential side of a central ceramic member having a wafer placement surface; and
a conductive base member having an outer circumferential support that supports the outer circumferential ceramic member, the conductive base member being joined to a lower surface of the outer circumferential ceramic member,
wherein an inner circumferential surface of the outer circumferential ceramic member changes in diameter in an up-down direction, the inner circumferential surface of the outer circumferential ceramic member being a tapered surface which has a larger diameter at an upper position or a smaller diameter at an upper position.
